(19) United States
(12) Patent Application Publication
(10) Pub. No.: US 2003/0228736 A1
(43) Pub. Date: Dec. 11, 2003

(54) Semiconductor device and manufacturing method thereof

(75) Inventor: Masatoshi Kimura, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/335,912

(22) Filed: Jan. 3, 2003

(30) Foreign Application Priority Data
Jun. 10, 2002 (JP) 2002-168346(P)

(51) Int. Cl. H01L 21/336; H01L 27/148; H01L 29/768

(52) U.S. Cl. 438/286; 257/227

(57) ABSTRACT

A P type channel dope impurity region and a P⁻ type punch-through stopper impurity region are not formed in a part of a channel region between an N⁻ type photodiode impurity region and an N⁺ type floating diffusion impurity region. As a result, it will be more difficult for a potential harrier or a potential drop to trap charges transferred from N⁻ type photodiode impurity region to N⁺ type floating diffusion impurity region. Consequently, since the charges generated in the photodiode impurity region is more easily transferred, a semiconductor device is obtained which has a solid-state image pickup element using a charge transfer transistor in which degradation of an image quality due to noise is suppressed.

### BACKGROUND OF THE INVENTION

1. Field of the Invention

The present invention relates to a semiconductor device having a transistor and a manufacturing method thereof.

2. Description of the Background Art

An example of a semiconductor device having a transistor is a semiconductor device having a solid-state image pickup element, in which one of source/drain regions forming the transistor is a photodiode impurity region, while the other source/drain region is a floating diffusion impurity region.

In such a semiconductor device, charges are generated by a photoelectric conversion in the photodiode impurity region. In addition, such a semiconductor device has a charge transfer gate guiding the charges generated in the photodiode impurity region to the floating diffusion impurity region. Furthermore, the degree of change in potential in the floating diffusion impurity region is amplified with an amplifier provided to each pixel (picture element), and the result is output to the outside of the pixel. Since the semiconductor device as described above functions as an optical sensor, it is used as a solid-state image pickup element.

There are two kinds of solid-state image pickup elements. One is a complete transfer-type pixel which can completely transfer the charges generated in the photodiode impurity region to the floating diffusion impurity region, and the other is an incomplete transfer-type pixel which cannot transfer all of the charges from the photodiode impurity region to the floating diffusion impurity region. The details thereof are described in “Base of Solid State Image Sensor (Fundamentals of solid-state image pickup element)” by Takao Ando et al., especially in the chapter about an afterimage on p. 162.

Each of the complete and incomplete transfer-type pixels is not described in detail herein. In this specification, the solid-state image pickup element having the complete transfer-type pixel will be described. A structure of a conventional solid-state image pickup element having the complete transfer-type pixel is shown in FIGS. 3-42 on p. 89 in the aforementioned “Base of Solid State Image Sensor”.

An operation of the solid-state image pickup element having the complete transfer-type pixel is as follows. The charges generated in the photodiode impurity region are guided to the amplifier, utilizing a switching of a charge transfer transistor. A difference in an amount of the charges generated in the photodiode impurity region is converted to a difference in a voltage change in the amplifier, and the result is output to the outside.

The photodiode impurity region is generally formed with very low concentration of the impurity. Thus, the photodiode impurity region is completely depleted by reverse biasing.

The floating diffusion impurity region and a source/drain region of a common transistor forming a logic portion have similar structures. The transistor, wherein either one of the source region or the drain region as described above is the photodiode impurity region which accumulates the charges by the photoelectric conversion, is referred to as a charge transfer transistor hereinafter.

In the conventional solid-state image pickup element, an impurity which determines a threshold voltage Vₜₕ of a transistor is injected into a channel region directly below a gate insulator film of the charge transfer transistor. This impurity, for example, is a channel dope impurity B (boron) for an NMOS (N Channel Metal Oxide Semiconductor).

In a PMOS (P Channel Metal Oxide Semiconductor), an impurity B (boron) for forming a channel (counter) dope impurity region, or an impurity for forming a punch-through stopper impurity region to suppress the punch-through is injected into a channel region directly below a gate insulator film of the charge transfer transistor. In particular, the impurity for the punch-through stopper impurity region has a conductivity type opposite to that of the impurity included in the photodiode impurity region.

Consequently, in the channel dope impurity region or the punch-through stopper impurity region, there is formed a potential barrier or a potential drop (a portion where a potential is extremely lowered) which will interfere with the charge transfer when the charges are transferred from the photodiode impurity region to the floating diffusion region. The potential barrier or the potential drop interferes with the transfer of the charges generated in the photodiode. As a result, a noise such as an afterimage is disadvantageously generated in the solid-state image pickup element.

In addition, distribution of the concentration of the impurity in the channel region directly below the charge transfer gate insulator film and the photodiode impurity region is nonuniform. Thus, the potential barrier or the potential drop is formed in the channel region and the photodiode impurity region. As a result, the charges generated in the photodiode impurity region are trapped in the potential barrier or the potential drop. Consequently, not all of the charges generated in the phototransistor impurity region can be transferred to the floating diffusion impurity region.

A structure of the aforementioned conventional charge transfer transistor will specifically be described with reference to FIG. 13.

As shown in FIG. 13, the structure of the region near the conventional charge transfer transistor is as follows. An element isolation insulator film 2 is formed to extend from a position of a prescribed depth from the main surface of a P type semiconductor substrate 1 to a position upper than the surface of P type semiconductor substrate 1. A charge transfer gate electrode 4 forming the charge transfer transistor is provided in an element formation region which is isolated with this element isolation insulator film 2.

Furthermore, a charge transfer gate insulator film 3 is provided between charge transfer gate electrode 4 and the main surface of P type semiconductor substrate 1. A sidewall insulator film 5 is provided on the side walls of charge transfer gate electrode 4 and charge transfer gate insulator film 3.

In addition, a P type channel dope impurity region 6 is provided over the whole region enclosed with element isolation insulator film 2. An N⁻ type low concentration impurity region 7 is provided in the region between the lower side of charge transfer gate insulator film 3 and the lower side of element isolation insulator film 2.

In addition, an N⁺ type high concentration impurity region 8 which has an impurity concentration higher than that of the aforementioned N⁻ type low concentration impurity region 7 is provided in the region between the lower side of sidewall insulator film 5 and the lower side of element isolation insulator film 2. An N⁺ type floating diffusion impurity region 9 is formed with N⁻ type low concentration impurity region 7 and N⁺ type high concentration impurity region 8.

In addition, an N⁻ type photodiode impurity region 10 is formed in the region on that side of gate electrode 4 opposite to N+type floating diffusion impurity region 9. A P⁻ type punch-through stopper impurity region 11 is formed to extend from the main surface of P type semiconductor substrate 1 to the position deeper than P type channel dope impurity region 6 mentioned above. A P⁻ type well 40 is formed below punch-through stopper impurity region 11.

In the conventional charge transfer transistor as shown in FIG. 13, P type channel dope impurity region 6 and P⁻ type punch-through stopper impurity region 11 are formed over the whole channel region of the charge transfer transistor.

P type channel dope impurity region 6 is provided to adjust the threshold voltage of the charge transfer transistor. P⁻ type punch-through stopper impurity region 11 is provided to suppress the punch-through phenomenon between N⁺ type floating diffusion impurity region 9 and N⁻ type photodiode impurity region 10.

Another example of the conventional charge transfer transistor will now be described with reference to FIG. 14. In this example of the conventional charge transfer transistor shown in FIG. 14, the same characters indicate the portions similarly function as those in the conventional charge transfer transistor shown in FIG. 13.

As shown in FIG. 14, in the structure of the region near this example of the conventional charge transfer transistor 70, another transistor 80 having a gate electrode 14, a gate insulator film 13 and a sidewall insulator film 15 is formed beside charge transfer transistor 70.

A contact plug 16 connected to N⁺ type floating diffusion impurity region 9 is provided between charge transfer transistor 70 and another transistor 80. Contact plug 16 is formed to penetrate an interlayer insulator film 20 in the direction perpendicular to the main surface of P type semiconductor substrate 1.

Processes for manufacturing the charge transfer transistor shown in FIG. 13 will now be described with reference to FIGS. 15 and 16. In the method of manufacturing the charge transfer transistor shown in FIG. 13, first, as shown in FIG. 15, charge transfer gate electrode 4, sidewall insulator film 5, N⁺ type floating diffusion impurity region 9, and element isolation insulator film 2 are covered with a resist film 30 prior to the step of forming N⁻ type photodiode impurity region 10.

Then, the impurity is injected obliquely as shown by an arrow 50 to form N⁻ type photodiode impurity region 10 extending to the region below charge transfer gate insulator film 3. With this, N⁻ type photodiode impurity region 10 is formed as shown in FIG. 16.

In the conventional solid-state image pickup element shown in FIG. 13, P type channel dope impurity region 6 and P type punch-through stopper impurity region 11 have the conductivity type opposite to that of N⁻ type photodiode impurity region 10. Therefore, the potential barrier or the potential drop is formed in P type channel dope impurity region 6 and P⁻ type punch-through stopper impurity region 11.

Thus, a part of the charges generated in N⁻ type photodiode impurity region 10 are trapped in the potential barrier or the potential drop. That means, some of the charges generated in N⁻ type photodiode impurity region 10 will not be transferred to N⁺ type floating diffusion impurity region 9. As a result, a noise is disadvantageously generated and the image quality is degraded in the solid-state image pickup element.

In this example of the conventional solid-state image pickup element shown in FIG. 14, the distance between contact plug 16 and charge transfer gate electrode 4 is sometimes extremely small. In such a case, a parasitic capacitance is generated between charge transfer gate electrode 4 and contact plug 16. Such parasitic capacitance is a serious problem in the solid-state image pickup element, which causes degradation of the image quality of the solid-state image pickup element.

Furthermore, in the processes of manufacturing the solid-state image pickup element in FIG. 13 as shown in FIGS. 15 and 16, the impurity is injected into the side walls of charge transfer gate electrode 4 and charge transfer gate insulator film 3. As a result, properties of charge transfer gate electrode 4 and charge transfer gate insulator film 3 are degraded.

### SUMMARY OF THE INVENTION

A first object of the present invention is to provide a semiconductor device which has a transistor in which transfer of charges generated in one source/drain region forming the transistor to the other source/drain region is less interfered.

A second object of the present invention is to provide a semiconductor device which has a decreased parasitic capacitance between a gate electrode and a conductive contact portion connected to a source/drain region.

A third object of the present invention is to provide a semiconductor device which suppresses degradation of properties of a gate electrode and a gate insulator film, and to provide a manufacturing method thereof.

A semiconductor device in the first aspect of the present invention includes a semiconductor substrate, a gate insulator film provided on the semiconductor substrate, a gate electrode provided on the gate insulator film, a channel region located below the gate electrode in the semiconductor substrate, a source region and a drain region provided so as to sandwich the channel region therebetween, and a channel dope impurity region provided in the channel region and determining a threshold voltage applied to the gate electrode when the source region and the drain region are brought into conduction. In the channel region, the channel dope impurity region is provided only in a portion of the channel region.

In accordance with the above-described structure, the degree of the interference with the charge transfer in the channel region, which interference is caused by the potential barrier or the potential drop existing in the channel dope impurity region, is decreased.

A semiconductor device in a second aspect of the present invention includes a charge transfer transistor transferring charges generated in a photoelectric conversion element portion, and another transistor having a function different from that of the charge transfer transistor. In addition, the semiconductor device in the second aspect of the present invention includes a charge transfer channel region provided below a gate electrode of the charge transfer transistor, and another channel region provided below the aforementioned another transistor. While a channel dope impurity region determining a threshold voltage of the aforementioned another transistor is provided in the aforementioned another channel region, the channel dope impurity region is not provided in the charge transfer channel region. In other words, the channel dope impurity regions provided except in the change transfer channel region.

In accordance with the above-described structure, the interference with the charge transfer in the channel region, which interference is caused by the potential barrier or the potential drop existing in the channel dope impurity region, is prevented in the channel region of the charge transfer transistor.

A semiconductor device in a third aspect of the present invention includes a charge transfer transistor transferring charges generated in a photoelectric conversion element portion, and another transistor having a function different from that of the charge transfer transistor. Thickness of a charge transfer gate insulator film of the charge transfer transistor is larger than that of a gate insulator film of a gate electrode of the aforementioned another transistor.

In accordance with the above-described structure, when the charge transfer transistor having a charge transfer gate electrode has the same threshold voltage as the transistor having a gate electrode, the voltage applied to the charge transfer gate electrode can be increased so that the voltage applied to the charge transfer gate electrode will be higher than the threshold voltage. As a result, since the transfer loss of the charges transferred by the charge transfer transistor is decreased, an image quality of an image pickup element can be enhanced.

A semiconductor device in a fourth aspect of the present invention includes a charge transfer transistor transferring charges generated in a photoelectric conversion element portion, and another transistor having a function different from that of the charge transfer transistor. Thickness of a charge transfer gate insulator film of the charge transfer transistor is smaller than that of a gate insulator film of the aforementioned another transistor.

In accordance with the above-described structure, the charge transfer gate electrode has an electric field larger than that in the gate electrode in the direction perpendicular to the main surface of the semiconductor substrate. Therefore, the thickness of the charge transfer gate insulator film can be set such that, when the charges generated in the photoelectric conversion element are trapped in the potential barrier or the potential drop, the charges can be returned to the channel region with the electric field in the gate electrode. As a result, because the transfer loss of the charges transferred by the charge transfer transistor is decreased, the image quality of the solid-state image pickup element can be enhanced.

A semiconductor device in a fifth aspect of the present invention includes a charge transfer transistor transferring charges generated in a photoelectric conversion element, and another transistor having a function different from that of the charge transfer transistor. A charge transfer gate insulator film of the charge transfer transistor includes a thick film portion having the same thickness as a gate insulator film of the aforementioned another transistor, and a thin film portion which is thinner in comparison with the thick film portion.

In accordance with the above-described structure, reliability of the charge transfer gate insulator film can be maintained in the thick film portion. In addition, the thickness of the thin film portion can be set such that, when the charges generated in the photoelectric conversion element portion are trapped in the potential barrier or the potential drop in the photoelectric conversion element portion, the charges can be returned to the channel region with the electric field in the gate electrode. As a result, because the transfer loss of the charges transferred by the charge transfer transistor is decreased, the image quality of the solid-state image pickup element can be enhanced.

A semiconductor device in a sixth aspect of the present invention includes a semiconductor substrate, a source region and a drain region formed to extend from the main surface of the semiconductor substrate to a prescribed depth, a gate electrode formed above an upper side of the semiconductor substrate in a region between the source region and the drain region, a gate insulator film formed between the gate electrode and the semiconductor substrate, and a contact conductive portion connected to the source region or the drain region. The gate electrode includes a high concentration portion having a relatively high impurity concentration, and a low concentration portion having a relatively low impurity concentration. The low concentration portion and the contact conductive portion are opposite to each other.

In accordance with the above-described structure, a parasitic capacitance generated between the contact conductive portion and the gate electrode can be decreased.

A semiconductor device in a seventh aspect of the present invention includes a semiconductor substrate, a source region and a drain region formed to extend from the main surface of the semiconductor substrate to a prescribed depth, a gate electrode formed on an upper side of the semiconductor substrate in a region between the source region and the drain region, a gate insulator film formed between the gate electrode and the semiconductor substrate, and a contact conductive portion connected to the source region or the drain region. The gate electrode includes a thick film portion which is relatively thick, and a thin film portion which is relatively thin. The thin film portion and the contact conductive portion are opposite to each other.

In accordance with the above-described structure, a parasitic capacitance generated between the contact conductive portion and the gate electrode can be decreased.

A semiconductor device in an eighth aspect of the present invention includes a semiconductor substrate, a source region and a drain region formed to extend from the main surface of the semiconductor substrate to a prescribed depth, a gate electrode formed on an upper side of the semiconductor substrate in a region between the source region and the drain region, and a gate insulator film formed between the gate electrode and the semiconductor substrate. The gate electrode and the gate insulator film do not include an impurity forming the source region or the drain region.

In accordance with the above-described structure, a decrease in reliability of the gate electrode and the gate insulator film can be prevented, which decrease is caused by the gate electrode and the gate insulator film including the impurity forming the source region or the drain region.

A method of manufacturing a semiconductor device of a first aspect of the present invention includes the steps of: forming an element isolation insulator film to form an element formation region on a semiconductor substrate; forming a mask layer having an opening on a part of the element formation region; forming an impurity region extending from the main surface of the semiconductor substrate to a prescribed depth by injecting an impurity using the mask layer as a mask; and forming a gate insulator film and a gate electrode on the semiconductor substrate near the impurity region after the step of forming the impurity region, so as to make the impurity region a source region or a drain region of a transistor.

In accordance with the above-described manufacturing method, a semiconductor device having a gate electrode and a gate insulator film which do not include an impurity forming a source region or a drain region can be manufactured.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 9 respectively show structures of semiconductor devices in first to ninth embodiments.

FIGS. 10 and 11 show a manufacturing method of a semiconductor device in a tenth embodiment.

FIG. 12 shows a structure and a manufacturing method of the semiconductor device in the tenth embodiment.

FIG. 13 shows a structure of a conventional semiconductor device.

FIG. 14 shows a structure of another example of the conventional semiconductor device.

FIGS. 15 and 16 show a manufacturing method of the conventional semiconductor device.

### DESCRIPTION OF THE PREFERRED EMBODIMENTS

(First Embodiment)

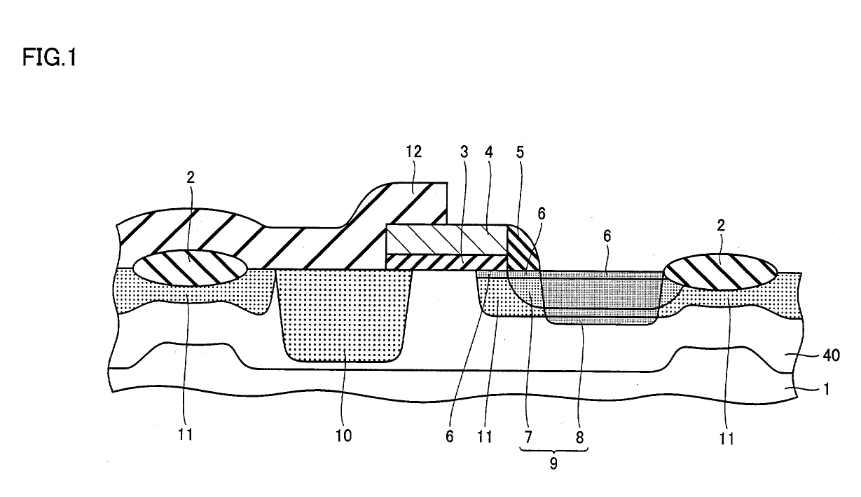

A semiconductor device of a first embodiment of the present invention will now be described with reference to FIG. 1.

As shown in FIG. 1, the semiconductor device of this embodiment has a structure as follows. Element isolation insulator film 2 isolating an element formation region is formed near the main surface of P type semiconductor substrate 1. A charge transfer transistor is provided in a region enclosed with element isolation insulator film 2. The charge transfer transistor has charge transfer gate electrode 4 and charge transfer gate insulator film 3. A sidewall insulator film 5 is provided on the side walls of charge transfer gate insulator film 3 and charge transfer gate electrode 4.

In P type semiconductor substrate 1, P type channel dope impurity region 6 is provided between a prescribed position below charge transfer gate insulator film 3 and element isolation insulator film 2. In addition, in P type semiconductor substrate 1, N⁻ type low concentration impurity region 7 is formed to extend from the main surface of P type semiconductor substrate 1 to a prescribed depth in the region between the lower side of the end of charge transfer gate insulator film 3 and the lower side of element isolation insulator film 2.

In addition, in P type semiconductor substrate 1, N⁺ type high concentration impurity region 8 which has an impurity concentration higher than that of the aforementioned N⁻ type low concentration impurity region 7 is formed in the region between the lower side of the end of sidewall insulator film 5 and the lower side of element isolation insulator film 2. N⁺ type floating diffusion impurity region 9 is formed with N⁻ type low concentration impurity region 7 and N⁺ type high concentration impurity region 8.

In addition, N⁻ type photodiode impurity region 10 is formed to extend from the main surface of P type semiconductor substrate 1 to a prescribed depth in the region on that side of charge transfer gate electrode 4 opposite to N⁺ type floating diffusion impurity region 9. P⁻ type punch-through stopper impurity region 11 is formed in the region below the above-mentioned P type channel dope impurity region 6 and the region below element isolation insulator film 2. P⁻ type well 40 is formed below punch-through stopper impurity region 11. In addition, a sidewall insulator film 12 is formed to cover the side walls of charge transfer gate electrode 4 and charge transfer gate insulator film 3.

In the charge transfer transistor of this embodiment shown in FIG. 1, the region not including P type channel dope impurity region 6 and P⁻ type punch-through stopper impurity region 11 is provided in the channel region between N⁻ type photodiode impurity region 10 and N⁺ type floating diffusion impurity region 9. That is, P type channel dope impurity region 6 and P⁻ type punch-through stopper impurity region 11 are provided only in a portion of the channel region.

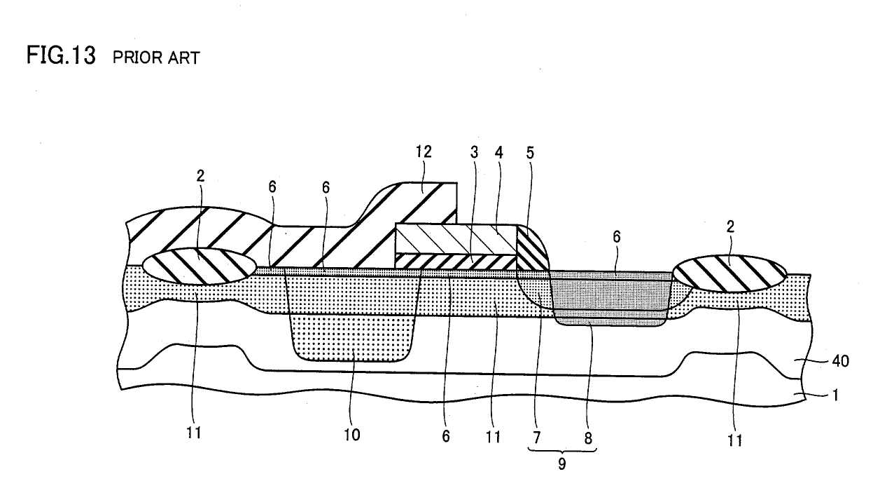

In the conventional charge transfer transistor shown in FIG. 13, P type channel dope impurity region 6 and P⁻ type punch-through stopper impurity region 11 are formed over the whole channel region between N⁻ type photodiode impurity region 10 and N⁺ type floating diffusion impurity region 9.

Consequently, the length of the region generating the potential barrier or the potential drop in the channel region in the direction parallel to the main surface of P type semiconductor substrate 1 is shorter in the charge transfer transistor of this embodiment than in the conventional charge transfer transistor shown in FIG. 13. Thus, the degree of the charges generated in N⁻ type photodiode impurity region 10 being trapped in the potential barrier or the potential drop in the channel region is decreased. Therefore, according to the charge transfer transistor of this embodiment, the noise of the solid-state image pickup element is decreased. As a result, the image quality of the image pickup element is enhanced.

In addition, P type channel dope impurity region 6 and P⁻ type punch-through stopper impurity region 11 are also not formed in N⁻ type photodiode impurity region 10. Thus, the degree of the charges generated in N⁻ type photodiode impurity region 10 being trapped in the potential barrier or the potential drop in N⁻ type photodiode impurity region 10 is decreased. As a result, the image quality of the image pickup element is further enhanced.

(Second Embodiment)

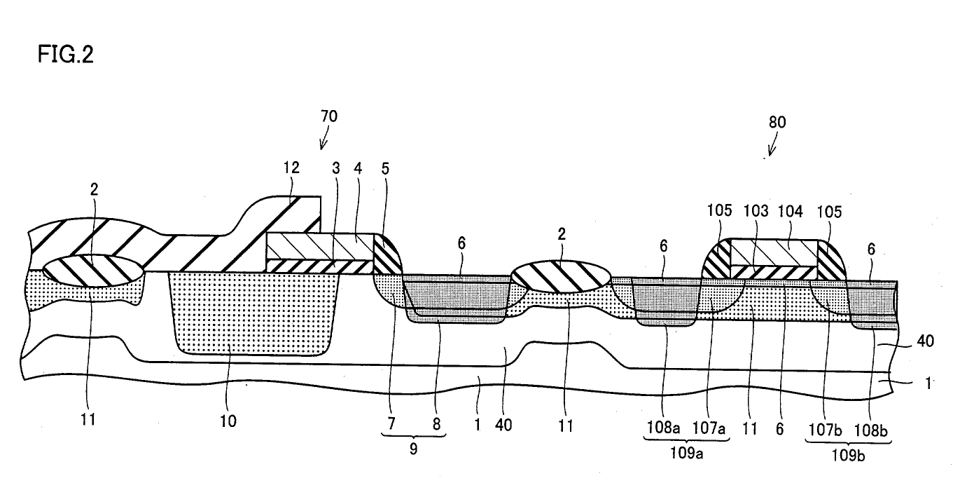

A structure of a semiconductor device of a second embodiment will now be described with reference to FIG. 2.

As shown in FIG. 2, a charge transfer transistor of this embodiment has a structure similar to that of the charge transfer transistor of the first embodiment. Similar to the structure of the charge transfer transistor as described in the first embodiment with reference to FIG. 1, in the structure of the charge transfer transistor of this embodiment, P type channel dope impurity region 6 and P⁻ type punch-through stopper impurity region 11 are not formed in N⁻ type photodiode impurity region 10. Thus, as the semiconductor device of the first embodiment, the degree of the charges generated in N⁻ type photodiode impurity region 10 being trapped in the potential barrier or the potential drop in N⁻ type photodiode impurity region 10 is decreased.

In the charge transfer transistor shown in FIG. 2, however, P type channel dope impurity region 6 is formed only in the region between the lower side of the end of element isolation insulator film 2 and the lower side of that end of sidewall insulator film 5, which end is on the opposite side to gate electrode 4. Furthermore, P⁻ type punch-through stopper impurity region 11 is formed only in the region between the lower side of element isolation insulator film 2 and the lower side of the end of charge transfer gate insulator film 3.

This means that, in the charge transfer transistor of this embodiment, P type channel dope impurity region 6 is not formed in the channel region between N⁻ type photodiode impurity region 10 and N⁺ type floating diffusion impurity region 9. In other words, P type channel dope impurity region 6 is formed except in the change region between N⁻ type photodiode impurity region 10 and N⁺ type floating diffusion impurity region 9.

It is to be noted that, P type channel dope impurity region 6, which is formed in the element formation region wherein charge transfer transistor 70 is formed, does not function as a channel dope impurity region in charge transfer transistor 70, because it is not formed in the channel region of charge transfer transistor 70.

P type channel dope impurity region 6 functions as a channel dope impurity region, however, in another transistor 80 such as a reset transistor, an amplifier and a switch transistor, and a transistor of a logic circuit, for example. In addition, P type channel dope impurity region 6, which is formed in the element formation region wherein charge transfer transistor 70 is formed, is simultaneously formed in a step of forming the channel dope impurity region of another transistor 80. Therefore, approximately the same distributions of the impurity in the direction perpendicular to the main surface of P type semiconductor substrate 1 are obtained in P type channel dope impurity region 6 of charge transfer transistor 70 and channel dope impurity region 6 of another transistor 80. In addition, the impurities for P type channel dope impurity region 6 of charge transfer transistor 70 and channel dope impurity region 6 of another transistor 80 are of the same type.

In addition, in charge transfer transistor 70 of this embodiment, P⁻ type punch-through stopper impurity region 11 is not formed in the region below charge transfer gate insulator film 3. In other words, P⁻ type punch-through stopper impurity region 11 is formed except in the region below change transfer gate insulating film 3.

It is to be noted that, P⁻ type punch-through stopper impurity region 11, which is formed in the element formation region wherein charge transfer transistor 70 is formed, does not function as a punch-through stopper impurity region in charge transfer transistor 70, because it is not formed in the channel region.

P⁻ type punch-through stopper impurity region 11 functions as a punch-through stopper impurity region, however, in another transistor 80 such as a reset transistor, an amplifier and a switch transistor, and a logic circuit, for example. In addition, P⁻ type punch-through stopper impurity region 11, which is formed in the element formation region wherein charge transfer transistor 70 is formed, is simultaneously formed in a step of forming the impurity region of another transistor 80. Therefore, approximately the same distribution of the impurity in the direction perpendicular to the main surface of the semiconductor substrate as in the channel dope impurity region of the aforementioned another transistor is obtained. In addition, the impurities for P⁻ type punch-through stopper impurity region 11 and the channel dope impurity region of the aforementioned another transistor are of the same type.

In accordance with the charge transfer transistor of this embodiment as described above, both P type channel dope impurity region 6 and P⁻ type punch-through stopper impurity region 11 are not formed in the channel region. Therefore, in the charge transfer transistor of this embodiment, N⁻ type photodiode impurity region 10 can be formed in a position closer to N⁺ type floating diffusion impurity region 9.

As a result, the region in N⁻ type photodiode impurity region 10 which is located below charge transfer gate insulator film 3 can be enlarged. Thus, the amount of charges accumulated in N⁻ type photodiode impurity region 10 can be increased, and the S (signal)/N (noise) ratio can be enhanced.

As a way of injecting the impurity below charge transfer gate insulator film 3, it is contemplated to inject the impurity obliquely using element isolation insulator film 2, charge transfer gate insulator film 3 and gate electrode 4 as a mask. In such a situation, the size of N⁻ type photodiode impurity region 10 in the direction parallel to the main surface of P type semiconductor substrate 1 can be controlled by adjusting the angle of injection of the impurity.

In addition, a sufficient distance between N⁺ type floating diffusion impurity region 9 and N⁻ type photodiode impurity region 10 is ensured. Thus, the formation of the potential barrier or the potential drop due to the overlapping of N⁺ type floating diffusion impurity region 9 and N⁻ type photodiode impurity region 10 is suppressed.

If the impurity to form P⁻ type punch-through stopper impurity region 11 is not injected into the region directly below charge transfer gate insulator film 3 at all, the punch-through may easily be generated. In the charge transfer transistor shown in FIG. 2, however, generation of the leak current which flows between the source region and the drain region must be suppressed at the time of switching-on/off the current transfer transistor. For this purpose, the length of the gate of the current transfer transistor or, more precisely, the length of the channel must be increased. By increasing the length of the channel, the size of the chip is disadvantageously increased.

Therefore, when the suppression of increase in size of the chip is given priority, P type channel dope impurity region 6 and P⁻ type punch-through stopper impurity region 11 are formed in a part of the channel region below charge transfer gate insulator film 3, as the charge transfer transistor in the first embodiment. With this, the length of the channel can be decreased. As a result, the size of the pixel can be decreased, and the image quality of the solid-state image pickup element can be enhanced.

In the solid-state image pickup element of this embodiment, another transistor 80 is formed in the element formation region other than that element formation region in which charge transfer transistor 70 is formed. Another transistor 80 includes a gate electrode 104, a gate insulator film 103, and a sidewall insulator film 105. In addition, source/drain regions 109a, 109b are formed so as to sandwich a channel region below gate electrode 104 therebetween. Source/drain regions 109a, 109b are formed with low concentration impurity regions 107a, 107b and high concentration impurity regions 108a, 108b. A channel dope impurity region 106 is formed in the channel region. Punch-through stopper impurity region 11 is formed between source/drain regions 109a, 109b.

(Third Embodiment)

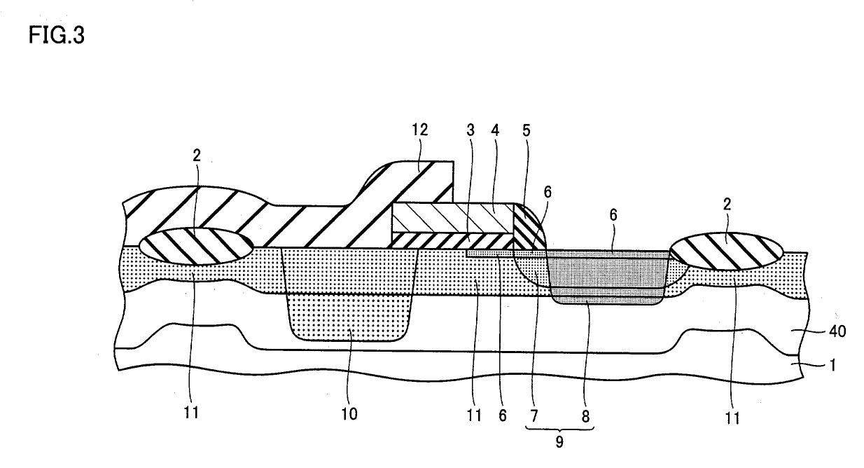

A semiconductor device of a third embodiment of the present invention will now be described with reference to FIG. 3.

As shown in FIG. 3, a charge transfer transistor of this embodiment has a structure similar to that of the charge transfer transistor of the first embodiment. In the charge transfer transistor shown in FIG. 3, however, P⁻ type punch-through stopper impurity region 11 is formed over the whole element formation region sandwiched between element isolation insulator films 2.

In the charge transfer transistor of the third embodiment, P type channel dope impurity region 6 is not formed in a part of the channel region, and P type channel dope impurity region 6 is not formed in N⁻ type photodiode impurity region 10 either. Therefore, according to the charge transfer transistor of the third embodiment, the effect similar to that obtained with the charge transfer transistor of the first embodiment can be obtained. That is, it can suppress the trap of the charges caused by the potential barrier or the potential drop of P type channel dope impurity region 6.

(Fourth Embodiment)

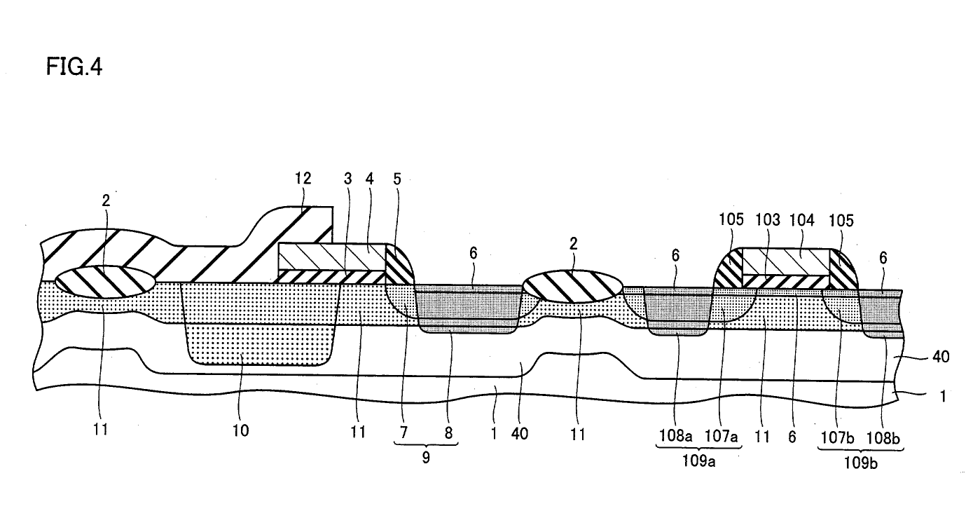

A semiconductor device of a fourth embodiment of the present invention will now be described with reference to FIG. 4.

A charge transfer transistor of the fourth embodiment shown in FIG. 4 has a structure similar to that of the charge transfer transistor of the second embodiment shown in FIG. 2. The structure is different, however, in that P⁻ type punch-through stopper impurity region 11 is formed over the whole element formation region enclosed with element isolation insulator film 2.

In the charge transfer transistor of the fourth embodiment, P type channel dope impurity region 6 is not provided in the channel region and N⁻ type photodiode impurity region 10. Therefore, according to the charge transfer transistor of this embodiment, the effect similar to that obtained with the charge transfer transistor of the second embodiment can be obtained. That is, it can suppress the trap of the charges caused by the potential barrier or the potential drop of P type channel dope impurity region 6.

(Fifth Embodiment)

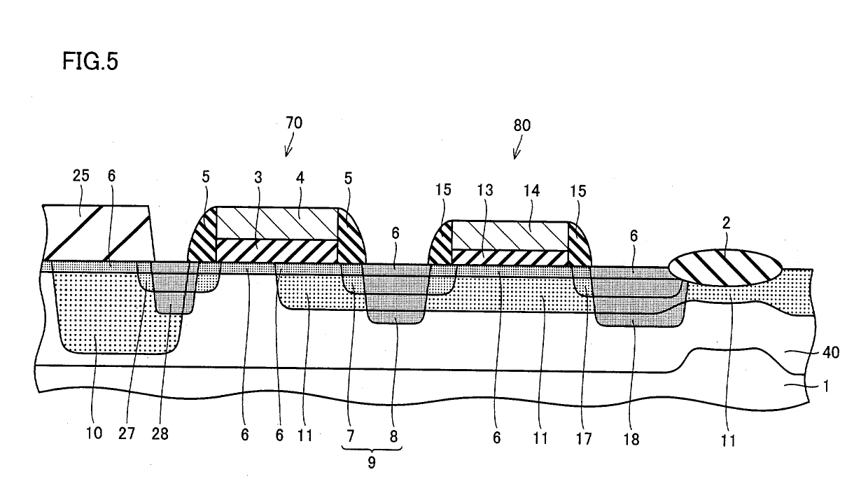

A semiconductor device of a fifth embodiment will now be described with reference to FIG. 5.

As shown in FIG. 5, the semiconductor device of the fifth embodiment has a structure as follows.

Element isolation insulator film 2 is provided near the main surface of P type semiconductor substrate 1. Charge transfer transistor 70 and another transistor 80 are provided in the region enclosed with element isolation insulator film 2. A reset transistor, a select transistor, or an AMI (Amplified MOS Intelligent Imager) transistor, for example, is contemplated as another transistor 80. In addition, charge transfer transistor 70 has charge transfer gate electrode 4 and charge transfer gate insulator film 3.

Furthermore, sidewall insulator film 5 is provided on the side walls of charge transfer gate electrode 4 and charge transfer gate insulator film 3. Another transistor 80 has gate electrode 14 and gate insulator film 13. Sidewall insulator film 15 is provided on the side walls of gate electrode 14 and gate insulator film 13.

In addition, P type channel dope impurity region 6 is provided to extend from the main surface of P type semiconductor substrate 1 to a prescribed depth over the whole element formation region. In P type semiconductor substrate 1, an N⁻ type low concentration impurity region 17 and an N⁺ type high concentration impurity region 18 which has an impurity concentration higher than that of N⁻ type low concentration impurity region 17 are provided in the region between the lower side of element isolation insulator film 2 and the lower side of sidewall insulator film 15. A source/drain region is formed with N⁻ type low concentration impurity region 17 and N⁺ type high concentration impurity region 18.

In addition, N⁻ type low concentration impurity region 7 and N⁺ type high concentration impurity region 8 which has an impurity concentration higher than that of N⁻ type low concentration impurity region 7 are provided in the region between the lower side of sidewall insulator film 15 and the lower side of sidewall insulator film 5. N⁺ type floating diffusion impurity region 9 of charge transfer transistor 70 is formed with N⁻ type low concentration impurity region 7 and N⁺ type high concentration impurity region 8.

In addition, in P type semiconductor substrate 1, P⁻ type punch-through stopper impurity region 11 is formed in the region between the lower side of the center portion of charge transfer gate insulator film 3 and the lower side of element isolation insulator film 2. P⁻ type well 40 is formed below punch-through stopper impurity region 11. An insulator film 25 is provided on that side of charge transfer transistor 70 which is opposite to another transistor 80.

In P type semiconductor substrate 1, an N⁻ type low concentration impurity region 27 and an N⁺ type high concentration impurity region 28 which has an impurity concentration higher than that of N⁻ type low concentration impurity region 27 are provided in the region between the lower side of insulator film 25 and the lower side of sidewall insulator film 5. Furthermore, in P type semiconductor substrate 1, N⁻ type photodiode impurity region 10 is provided in the region between the lower side of insulator film 25 and the lower side of the end of sidewall insulator film 5.

Generally, in the manufacturing process of the conventional charge transfer transistor shown in FIG. 13, N⁻ type photodiode impurity region 10 is formed below charge transfer gate insulator film 3 by injecting the impurity obliquely. Therefore, if the direction of the oblique injection is deviated, the charge transfer in N⁻ type photodiode impurity region 10 is interfered. As a result, the image quality is decreased in the solid-state image pickup element using the conventional charge transfer transistor shown in FIG. 13.

As in the solid-state image pickup element of this embodiment shown in FIG. 5, a contact plug (contact hole) is generally connected to N⁻ type photodiode impurity region 10. With this, N⁻ type photodiode impurity region 10 cannot completely be depleted, because the region such as N⁺ type high concentration impurity region 28 having high concentration of impurity must be formed within N⁻ type photodiode impurity region 10. As a result, the charge transfer transistor can only operate similarly to a normal MOS transistor.

Therefore, when the voltage lower than the threshold voltage of charge transfer transistor 70 is applied to charge transfer gate electrode 4, the charges generated in N⁻ type photodiode impurity region 10 move in the channel region only with diffusion. Because the moving speed of the charges is decreased accordingly, the image quality in the image pickup element is degraded so as to generate an afterimage.

For this reason, in the solid-state image pickup element of this embodiment shown in FIG. 5, charge transfer gate insulator film 3 forming charge transfer transistor 70 is made with thickness different from that of gate insulator film 13 forming another transistor 80. That is, charge transfer gate insulator film 3 of charge transfer transistor 70 has thickness larger than that of gate insulator film 13 of another transistor 80.

With this, the charge transfer transistor of this embodiment can obtain the effect as described below.

In general, when a voltage higher than a power supply voltage is applied to charge transfer gate electrode 4, reliability of charge transfer gate insulator film 3 is decreased. In the semiconductor device in this embodiment, however, the reliability of charge transfer gate insulator film 3 is enhanced since the thickness of charge transfer gate insulator film 3 of charge transfer transistor 70 is larger than that of the gate insulator film of another transistor 80.

Therefore, the voltage applied to charge transfer gate electrode 4 can be increased so that the voltage applied to gate electrode 4 of charge transfer transistor 70 will be higher than the threshold voltage Vₜₕ when the charges are transferred. That is, the voltage resulting from adding the power supply voltage which is higher than threshold voltage Vₜₕ to the threshold voltage can be applied to charge transfer gate electrode 4, for example.

As a result, generation of a voltage drop in the distribution of the threshold voltage between the source region and the drain region is suppressed. Therefore, the charges generated in N⁻ type photodiode impurity region 10 are prevented from being trapped by the potential barrier or the potential drop when transferred from N⁻ type photodiode impurity region 10 to N⁺ type floating diffusion impurity region 9. Thus, according to the image pickup element having charge transfer transistor 70 of this embodiment, the image quality can be enhanced without decreasing the reliability of charge transfer gate insulator film 3.

(Sixth Embodiment)

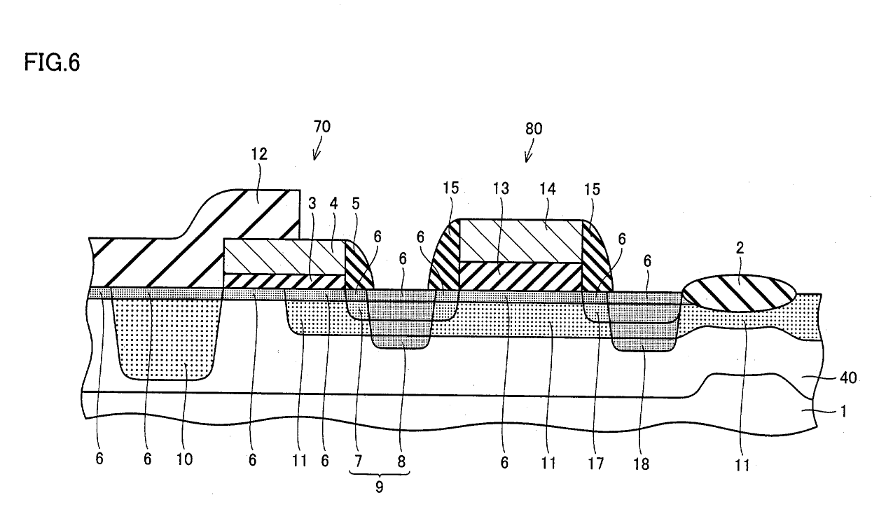

A semiconductor device of a sixth embodiment of the present invention will now be described with reference to FIG. 6.

Though the solid-state image pickup element of this embodiment shown in FIG. 6 is similar to that of the fifth embodiment shown in FIG. 5, it is different in the following points.

In contrast with the solid-state image pickup element of the fifth embodiment shown in FIG. 5, N⁻ type low concentration impurity region 27 and N⁺ type high concentration impurity region 28 are not formed in the solid-state image pickup element of this embodiment shown in FIG. 6. Furthermore, in contrast with the solid-state image pickup element of the fifth embodiment shown in FIG. 5, sidewall insulator film 12 in place of insulator film 25 and one sidewall insulator film 5 is formed in the solid-state image pickup element of this embodiment shown in FIG. 6.

In the solid-state image pickup element of the fifth embodiment shown in FIG. 5, charge transfer gate insulator film 3 of charge transfer transistor 70 has the thickness larger than that of gate insulator film 13 of another transistor 80. In the solid-state image pickup element of this embodiment, however, charge transfer gate insulator film 3 of charge transfer transistor 70 has the thickness smaller than that of gate insulator film 13 of another transistor 80. In the structure other than the points mentioned above, the solid-state image pickup element of this embodiment shown in FIG. 6 and the solid-state image pickup element of the fifth embodiment shown in FIG. 5 are identical with each other.

Compared with the case in which the thickness of gate insulator film 13 and that of charge transfer gate insulator film 3 are the same, in accordance with the solid-state image pickup element of this embodiment as described above, it will become more difficult for the potential barrier or the potential drop to trap the charges generated in N⁻ type photodiode impurity region 10 by an electric field generated in the direction perpendicular to the main surface of P type semiconductor substrate 1. That is, the charges trapped by the potential barrier or the potential drop are returned to the channel region by the electric field of charge transfer gate electrode 4. As a result, the image quality of the solid-state image pickup element using charge transfer transistor 70 of this embodiment is enhanced.

(Seventh Embodiment)

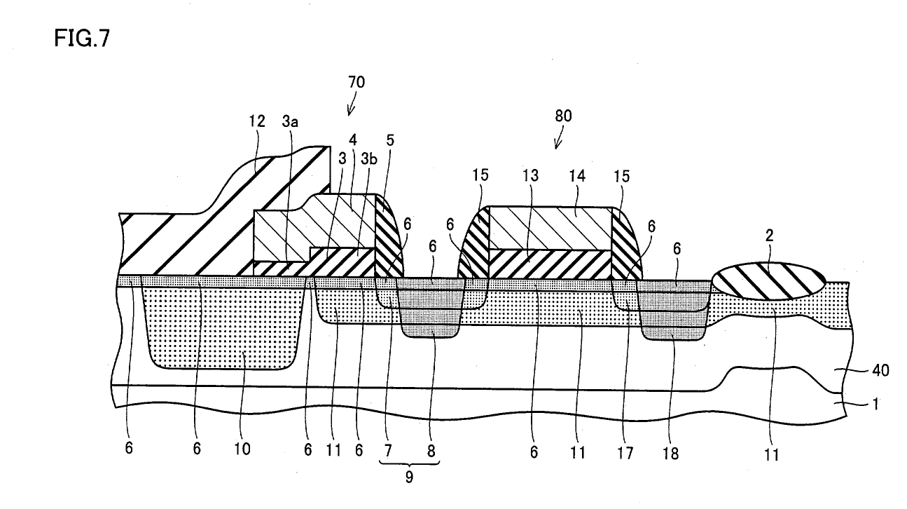

A semiconductor device of a seventh embodiment will now be described with reference to FIG. 7.

As shown in FIG. 7, a solid-state image pickup element of this embodiment has a structure similar to that of the solid-state image pickup element of the sixth embodiment shown in FIG. 6. There is a difference, however, in charge transfer transistor 70. In this transistor, charge transfer gate insulator film 3 is same in thickness as charge transfer gate insulator film 3 of another transistor 80 at a portion close to another transistor 80. At a portion far from another transistor 80, on the other hand, charge transfer gate insulator film 3 is thinner than charge transfer gate insulator film 3 of another transistor 80.

More specifically, the thickness of the portion of charge transfer gate insulator film 3 which is located above N⁻ type photodiode impurity region 10 is made smaller than that of the other portion of charge transfer gate insulator film 3 which is not located above N⁻ type photodiode impurity region 10. Thus, as shown in FIG. 7, charge transfer gate insulator film 3 has a thin film portion 3a and a thick film portion 3b.

In the aforementioned semiconductor device of the sixth embodiment shown in FIG. 6, the thickness of charge transfer gate insulator film 3 is made smaller throughout charge transfer gate insulator film 3. Thus, the gate capacitance is increased. As a result, a high-speed charge transfer cannot be performed in the charge transfer transistor.

In the solid-state image pickup element of this embodiment, however, the above-described problem is solved as follows.

In general, an electric field of charge transfer gate electrode 4 is generated in the direction perpendicular to the main surface of P type semiconductor substrate 1. In the charge transfer transistor 70 of this embodiment, the electric field generated in the region below thin film portion 3a will be larger than that generated in the region below thick film portion 3b. The effect of suppressing the trapping of the charges in the potential barrier or the potential drop by utilizing this large electric field is needed especially in N⁻ type photodiode impurity region 10.

Thus, in the solid-state image pickup element of this embodiment, the thickness of the film is made smaller only in the region below N⁻ type photodiode impurity region 10. As a result, according to the semiconductor device of this embodiment, the trapping of the charges in the potential barrier or the potential drop can be suppressed without sufficiently decreasing the speed of the charge transfer.

A manufacturing method to provide thin film portion 3a and thick film portion 3b in charge transfer gate insulator film 3 is described below.

First, an insulator film having a uniform thickness is formed as a preceding step of forming charge transfer gate insulator film 3. Only the partial region of the insulator film, which region will be the thick film portion, is then covered with a resist film. Thereafter, only a part of the upper side of the insulator film is etched by HF or the like using the resist film as a mask. With this method, a part of the lower side of the insulator film remains in the region which is not masked with the resist film, while the insulator film is not etched and the thickness remains unchanged in the region masked with the resist film.

(Eighth Embodiment)

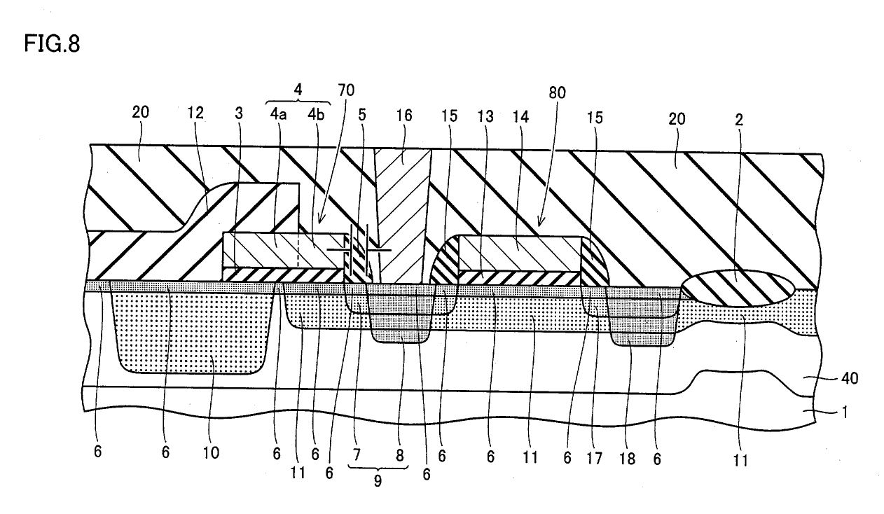

A semiconductor device of an eighth embodiment will now be described with reference to FIG. 8.

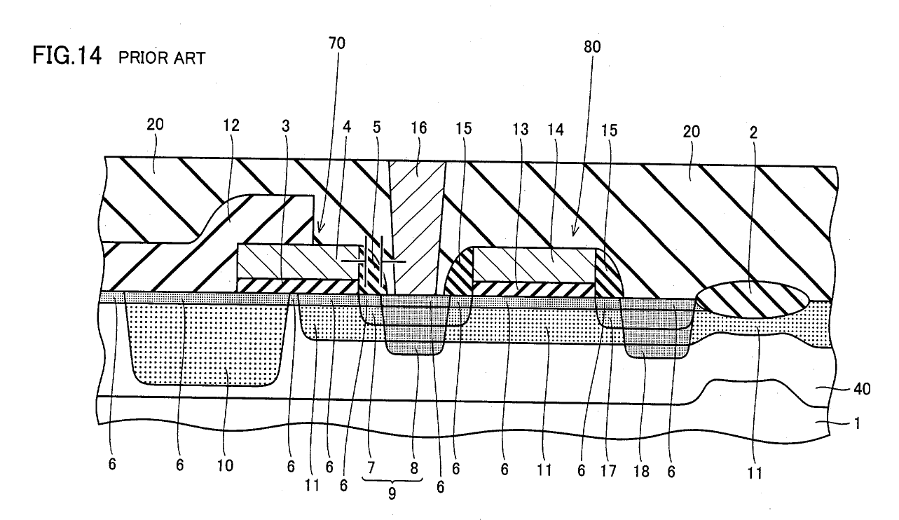

A structure of the solid-state image pickup element of the eighth embodiment shown in FIG. 8 is similar to that of the conventional solid-state image pickup element shown in FIG. 14. In contrast with the conventional solid-state image pickup element shown in FIG. 14, however, in the structure of the solid-state image pickup element of the eighth embodiment shown in FIG. 8, charge transfer gate electrode 4 forming charge transfer transistor 70 has a region 4a having a high impurity concentration and a region 4b having a low impurity concentration.

Gate electrode 4 having high concentration impurity region 4a and low concentration impurity region 4b is formed with a manufacturing method as described below. First, an impurity is injected into a polycrystalline silicon film as a preceding step of forming charge transfer gate electrode 4 such that, the whole polycrystalline silicon film as a preceding step of forming charge transfer gate electrode 4 will have the same impurity concentration as low concentration impurity region 4b after it is completely formed. Thereafter, the region to be low concentration impurity region 4b is masked, and the impurity of the same conductivity type as the impurity injected into low concentration impurity region 4b is further injected only into the region to be high concentration impurity region 4a.

Gate electrode 4 having high concentration impurity region 4a and low concentration impurity region 4b may also be formed with a manufacturing method as described below. First, a P type impurity is injected into a polycrystalline silicon film as a preceding step of forming charge transfer gate electrode 4 such that, the whole polycrystalline silicon film as a preceding step of forming charge transfer gate electrode 4 will have the same impurity concentration as high concentration impurity region 4a after it is completely formed. Thereafter, the region to be high concentration impurity region 4a is masked, and an N type impurity is further injected only into the region to be low concentration impurity region 4b.

According to the manufacturing method in which low concentration impurity region 4b is formed by injecting impurities of two different conductivity types into gate electrode 4, the concentration of impurity in the gate electrode can be made higher than with the manufacturing method in which high concentration impurity region 4a is formed by injecting the impurity of the same conductivity type twice into gate electrode 4. As a result, conductivity of the gate electrode can be enhanced.

In addition, the portion of charge transfer gate electrode 4 which is nearer to contact plug 16 is low concentration impurity region 4b. Thus, according to the solid-state image pickup element of this embodiment, the parasitic capacitance between contact plug 16 and gate electrode 4 can be decreased when compared with the example of making whole charge transfer gate insulator film 3 uniformly having the impurity concentration of high concentration impurity region 4a.

In addition, only the region of charge transfer gate electrode 4 which is located above N⁻ type photodiode impurity region 10 is high concentration impurity region 4a. In other words, in charge transfer gate electrode 4, the concentration of the impurity is made higher than other portions only in the region above N⁻ type photodiode impurity region 10, where it is highly needed to suppress the trapping of the charges in the potential barrier or the potential drop by the electric field of charge transfer gate electrode 4.

Therefore, in charge transfer transistor 70 of this embodiment, the response speed for the charge transfer is degraded only slightly, even when low concentration impurity region 4b is provided in charge transfer gate electrode 4. Therefore, according to charge transfer transistor 70 of this embodiment, the parasitic capacitance between contact plug 16 and gate electrode 4 can be decreased while not much decreasing the charge transfer speed.

As a result, the S/N ratio as a sensor of N⁺ type floating diffusion impurity region 9 which has a function of amplifying the signal photoelectrically converted in N⁻ type photodiode impurity region 10 can be enhanced.

(Ninth Embodiment)

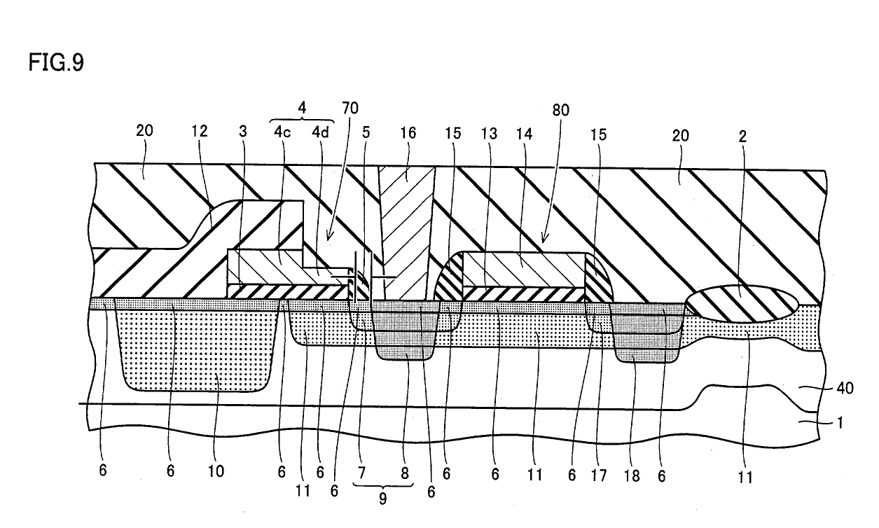

A semiconductor device of a ninth embodiment will now be described with reference to FIG. 9.

A structure of the solid-state image pickup element of this embodiment shown in FIG. 9 is similar to that of the conventional solid-state image pickup element described with FIG. 14. In contrast with charge transfer transistor 70 of the conventional solid-state image pickup element shown in FIG. 14 having gate electrode 4 of uniform thickness, however, in charge transfer transistor 70 of the solid-state image pickup element of this embodiment shown in FIG. 9, a portion of gate electrode 4 has thickness smaller than that of the other portion.

More specifically, gate electrode 4 has a thin film portion 4d in the portion nearer to contact plug 16, and a thick film portion 4c having thickness larger than that of thin film portion 4d in the portion further from contact plug 16. From a different viewpoint, thick film portion 4c is located above N⁻ type photodiode impurity region 10, while thin film portion 4d is not located above N⁻ type photodiode impurity region 10.

Therefore, according to charge transfer transistor 70 of this embodiment, the parasitic capacitance between contact plug 16 and charge transfer gate electrode 4 can be decreased when compared with the example of forming whole charge transfer gate insulator film 3 in uniform thickness. In addition, thick film portion 4c is provided only in the portion of charge transfer gate electrode 4, which portion is located above N⁻ type photodiode impurity region 10 and which, in particular, largely effects the charge transfer speed. In other words, the other portion of charge transfer gate electrode 4, which portion is not located above N⁻ type photodiode impurity region 10 and which is not particularly effects the charge transfer speed, is thin film portion 4d. Thus, there is only a small degree of degrading the response speed for the charge transfer.

As a result, according to charge transfer transistor 70 of this embodiment, the parasitic capacitance between contact plug 16 and gate electrode 4 can be decreased while not much decreasing the charge transfer speed.

A manufacturing method to provide thin film portion 4d and thick film portion 4c in charge transfer gate electrode 4 is described below.

First, a conductive silicon film having a uniform thickness is formed as a preceding step of forming charge transfer gate electrode 4. Only the region of the conductive silicon film, which region will be the thick film portion, is then covered with a resist film. Thereafter, only a part of the conductive silicon film is etched using the resist film as a mask. With this method, a part of the lower side of the conductive silicon film remains in the region which is not masked with the resist film, while the conductive silicon film is not etched and the thickness remains unchanged in the region masked with the resist film.

(Tenth Embodiment)

A solid-state image pickup element of a tenth embodiment and a manufacturing method of the solid-state image pickup element will now be described.

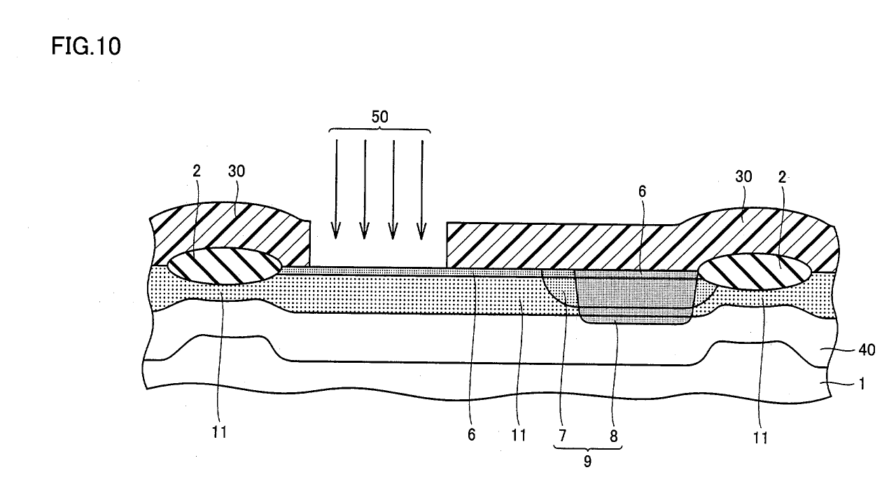

A structure of the solid-state image pickup element manufactured with the manufacturing method shown in FIGS. 10-12 is similar to that of the conventional solid-state image pickup element shown in FIG. 13.

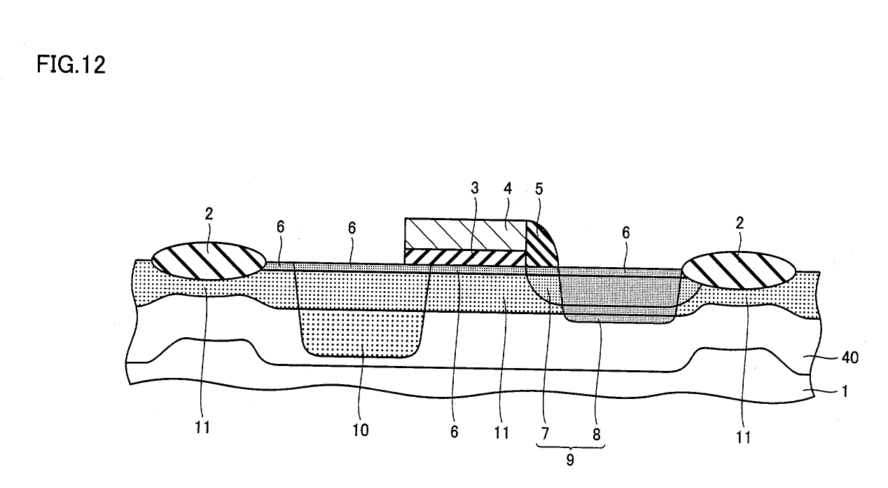

In the conventional charge transfer transistor shown in FIG. 13, the impurity which forms N⁻ type photodiode impurity region 10 is injected into the near end portion of charge transfer gate electrode 4 and charge transfer gate insulator film 3, which end portion is close to N⁻ type photodiode impurity region 10. In contrast, in the charge transfer transistor of this embodiment shown in FIG. 12, charge transfer gate electrode 4 and charge transfer gate insulator film 3 do not include the impurity which forms the source region or the drain region. The manufacturing method of the charge transfer transistor of this embodiment which has such a structure will be described with reference to FIGS. 10-12.

In the manufacturing method of the charge transfer transistor of this embodiment, element isolation insulator film 2 is first formed on the main surface of P type semiconductor substrate 1. N⁻ type low concentration impurity region 7, N⁺ type high concentration impurity region 8, P type channel dope impurity region 6, and P⁻ type punch-through stopper impurity region 11 are then formed to extend from the main surface of P type semiconductor substrate 1 to prescribed depths in the element formation region enclosed with the element isolation insulator film.

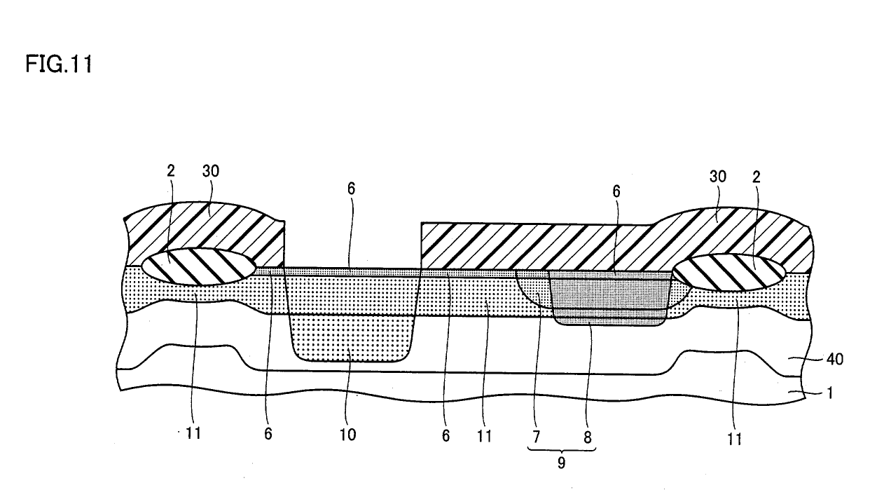

Thereafter, resist film 30 is provided on the main surface of P type semiconductor substrate 1 and on the surface of element isolation insulator film 2, so as to cover the region other than the region predetermined to form N⁻ type photodiode impurity region 10. The impurity is then injected in the direction perpendicular to the main surface of P type semiconductor substrate 1, as shown by arrow 50. With this, N⁻ type photodiode impurity region 10 is formed as shown in FIG. 11. Resist film 30 is then removed.

As shown in FIG. 12, charge transfer gate insulator film 3, charge transfer gate electrode 4 and sidewall insulator film 5 are then formed in the region between the upper side of the end portion of N⁻ type photodiode impurity region 10 and the upper side of the end portion of N⁺ type floating diffusion impurity region 9 formed with N⁻ type low concentration impurity region 7 and N⁺ type high concentration impurity region 8. By forming sidewall insulator film 12 thereafter, the semiconductor device having the structure as shown in FIG. 13 is formed.

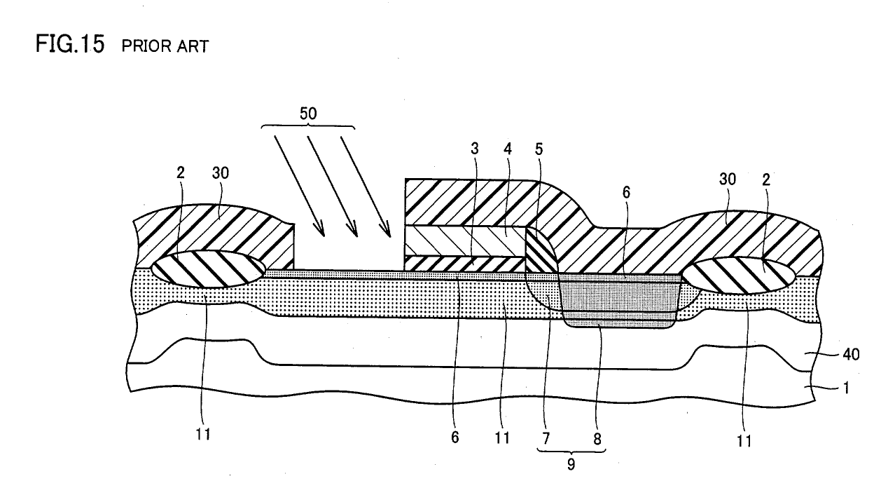

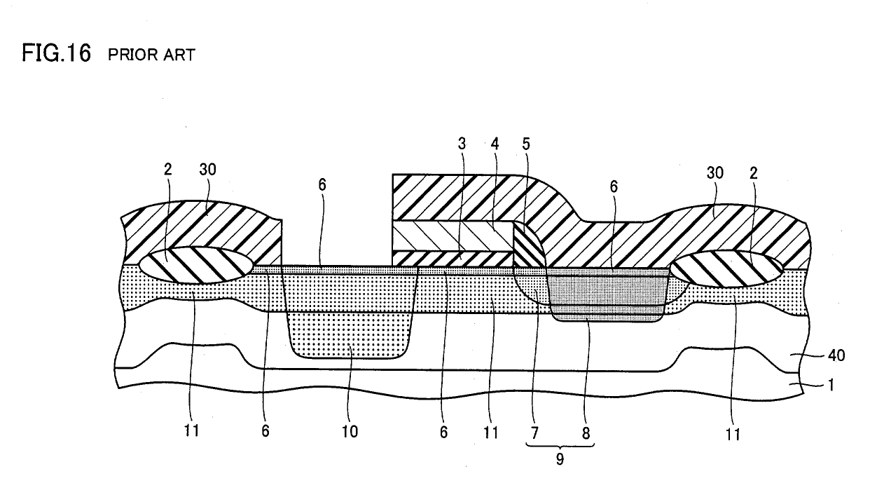

In the method of manufacturing the charge transfer transistor of this embodiment as described above, N⁻ type photodiode impurity region 10 is formed before charge transfer gate insulator film 3 and charge transfer gate electrode 4 are formed. Therefore, compared with the conventional method of manufacturing the charge transfer transistor as described with FIGS. 15 and 16, according to the method of manufacturing the charge transfer transistor of this embodiment, the degradation of the performance of charge transfer gate electrode 4 and charge transfer gate insulator film 3 is suppressed, which degradation is caused by injecting the impurity into the side walls of charge transfer gate electrode 4 and charge transfer gate insulator film 3.

It is to be noted that, either a thermally oxidized insulator film formed by oxidizing a main surface of a semiconductor substrate employing a LOCOS (LOCal Oxidation of Silicon) method, or a trench isolation insulator film formed by depositing an insulator film on a trench can be used as element isolation insulator film 2 of the semiconductor device in any of the first to tenth embodiments described above.

Though each of the elements of the semiconductor devices in the first to tenth embodiments described above is described as having a specific P or N conductivity type, the effects similar to that described in the first to tenth embodiments can be obtained even when the respective elements have conductivity types opposite to those used in the semiconductor device of each embodiment.

That is, the effects similar to that obtained with the semiconductor devices described in the respective first to tenth embodiments can be obtained, even when the elements including the P type impurity are changed to include the N type impurity and the elements including the N type impurity are changed to include the P type impurity in the semiconductor device in each embodiment.

Each element of the semiconductor device is indicated by a character in the drawings showing the prior art and each embodiment. The elements indicated by the same characters are formed for the same purpose, and are intended to have similar functions.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device, comprising:
a semiconductor substrate;
a gate insulator film provided on said semiconductor substrate;
a gate electrode provided on said gate insulator film;
a channel region located below said gate electrode in said semiconductor substrate;
a source region and a drain region provided so as to sandwich said channel region therebetween; and
a channel dope impurity region provided in said channel region and determining a threshold voltage applied to said gate electrode when said source region and said drain region are brought into conduction; wherein
in said channel region, said channel dope impurity region is provided only in a portion of said channel region.

2. The semiconductor device according to claim 1, wherein
a punch-through stopper impurity region suppressing a punch-through between said source region and said drain region is provided only in a portion of said channel region.

3. A semiconductor device, including
a charge transfer transistor transferring charges generated in a photoelectric conversion element portion, and
another transistor having a function different from that of said charge transfer transistor; said semiconductor device comprising:
a charge transfer channel region provided below a gate electrode of said charge transfer transistor; and
another channel region provided below said another transistor; wherein
said another channel region is provided with a channel dope impurity region determining a threshold voltage of said another transistor; and
said charge transfer channel region is not provided with said channel dope impurity region.

4. The semiconductor device according to claim 3, wherein
said charge transfer channel region is provided with a punch-through stopper impurity region suppressing a punch-through between a source region and a drain region, and
said another channel region is not provided with said punch-through stopper impurity region.

5. A semiconductor device, comprising:
a charge transfer transistor transferring charges generated in a photoelectric conversion element portion; and
another transistor having a function different from that of said charge transfer transistor; wherein
said charge transfer transistor has a charge transfer gate insulator film thicker than a gate insulator film of said another transistor.

6. A semiconductor device, comprising:
a charge transfer transistor transferring charges generated in a photoelectric conversion element portion; and
another transistor having a function different from that of said charge transfer transistor; wherein
said charge transfer transistor has a charge transfer gate insulator film thinner than a gate insulator film of said another transistor.

7. A semiconductor device, comprising:
a charge transfer transistor transferring charges generated in a photoelectric conversion element portion; and
another transistor having a function different from that of said charge transfer transistor; wherein
said charge transfer transistor has a charge transfer gate insulator film including a thick film portion which has the same thickness as a gate insulator film of said another transistor and a thin film portion which is thinner than said thick film portion.

8. The semiconductor device according to claim 7, wherein
said thin film portion is provided only in a region above said photoelectric conversion element portion.

9. The semiconductor device according to claim 7, wherein
said thin film portion is formed by selectively etching a part of an insulator film after said insulator film having the same thickness as said thick film portion is formed.

10. A semiconductor device, comprising:
a semiconductor substrate;
a source region and a drain region formed to extend from a main surface of said semiconductor substrate to a prescribed depth;
a gate electrode formed above said semiconductor substrate in a region between said source region and said drain region;
a gate insulator film formed between said gate electrode and said semiconductor substrate; and
a contact conductive portion connected to said source region or said drain region; wherein
said gate electrode includes a high concentration portion having a relatively high impurity concentration and a low concentration portion having a relatively low impurity concentration; and
said low concentration portion and said contact conductive portion are provided to be opposed to each other.

11. The semiconductor device according to claim 10, wherein
said high concentration portion is provided in a region above one of said source region and said drain region while the other of said source region and said drain region is connected with said contact conductive portion.

12. The semiconductor device according to claim 10, wherein
said low concentration portion is doped with impurities of two different conductivity types.

13. A semiconductor device, comprising:
a semiconductor substrate;
a source region and a drain region formed to extend from a main surface of said semiconductor substrate to a prescribed depth;
a gate electrode formed above said semiconductor substrate in a region between said source region and said drain region;
a gate insulator film formed between said gate electrode and said semiconductor substrate; and
a contact conductive portion connected to said source region or said drain region; wherein
said gate electrode includes a thick film portion having a relatively large thickness and a thin film portion having a relatively small thickness; and
said thin film portion and said contact conductive portion are provided to be opposed to each other.

14. The semiconductor device according to claim 13, wherein
said thick film portion is provided in a region above one of said source region and said drain region while the other of said source region and said drain region is connected with said contact conductive portion.

15. A semiconductor device, comprising:
a semiconductor substrate;
a source region and a drain region formed to extend from a main surface of said semiconductor substrate to a prescribed depth;
a gate electrode formed above said semiconductor substrate in a region between said source region and said drain region; and
a gate insulator film formed between said gate electrode and said semiconductor substrate; wherein
said gate electrode and said gate insulator film do not include an impurity forming said source region and said drain region.

16. A method of manufacturing a semiconductor device, comprising the steps of:
forming an element isolation insulator film to form an element formation region on a semiconductor substrate;
forming a mask layer having an opening on a part of said element formation region;
forming an impurity region extending from a main surface of said semiconductor substrate to a prescribed depth by injecting an impurity using said mask layer as a mask; and
forming a gate insulator film and a gate electrode above said semiconductor substrate near said impurity region after the step of forming said impurity region, so as to make said impurity region a source region or a drain region of a transistor.
